(19) United States
(12) Patent Application Publication
(10) Pub. No.: US 2025/0266362 A1
(43) Pub. Date: Aug. 21, 2025

(54) Semiconductor Device and Method of Making an Interconnect Bridge with Integrated Passive Devices

(71) Applicant: STATS ChipPAC Pte. Ltd., Singapore (SG)

(72) Inventors: YongTaek Lee, Seoul (KR); HeeSu Kim, Incheon (KR); JaeMyeong Kim, Incheon (KR); HeeSoo Lee, Incheon (KR); EunHee Myung, Gyeonggi-do (KR)

(73) Assignee: STATS ChipPAC Pte. Ltd., Singapore (SG)

(21) Appl. No.: 18/582,016

(22) Filed: Feb. 20, 2024

(51) Int. Cl. H01L 23/538; H01L 23/00; H01L 23/498; H01L 25/065

(52) U.S. Cl. CPC H01L 23/5381; H01L 23/49816; H01L 23/49838; H01L 24/05; H01L 24/45; H01L 24/97; H01L 25/0652; H01L 2224/05005; H01L 2224/05022; H01L 2224/45005; H01L 2224/4502; H01L 2224/97; H01L 2924/1205; H01L 2924/1206; H01L 2924/1207; H01L 2924/15311; H01L 2924/182

(57) ABSTRACT

A semiconductor device has a first substrate. A first semiconductor die and second semiconductor die are disposed over the substrate. An interconnect bridge is disposed over the first semiconductor die and second semiconductor die. The interconnect bridge has a second substrate. A conductive trace is formed over a first surface of the second substrate. The conductive trace is electrically coupled from the first semiconductor die to the second semiconductor die. A conductive via is formed through the second substrate. An IPD is formed over a second surface of the second substrate. The IPD is electrically coupled to the first semiconductor die or second semiconductor die through the conductive via. An encapsulant is deposited over the first substrate, first semiconductor die, second semiconductor die, and interconnect bridge.

### FIELD OF THE INVENTION

The present invention relates in general to semiconductor devices and, more particularly, to a semiconductor device and method of making an interconnect bridge with integrated passive devices.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Semiconductor devices may contain multiple electrical components, e.g., multiple semiconductor die and myriad discrete components to support the semiconductor die, disposed on one or more substrates to perform necessary electrical functions. Such a package is commonly referred to as a system-in-package (SiP) module. SiP modules can be formed with a plurality of semiconductor die interconnected to each other. Interconnecting the plurality of semiconductor die within a SiP module or other semiconductor package is a challenge in the prior art.

Another problem with SiP modules in the prior art is finding sufficient footprint space for all the required passive elements. Integrated passive devices can be formed over the semiconductor die, but there may not be enough footprint space available for all the required passive elements for a given SiP module design. Discrete passive devices require even more footprint outside of the semiconductor die.

### BRIEF DESCRIPTION OF THE DRAWINGS

FIGS. 1a-1c illustrate a semiconductor wafer with a plurality of semiconductor die separated by a saw street;

FIGS. 2a-2p illustrate forming an interconnect bridge with integrated passive devices using a through-silicon via process;

FIGS. 3a-3d illustrate forming a SiP module or semiconductor package with multiple semiconductor die connected to each other by the interconnect bridge;

FIGS. 4a-4d illustrate alternative embodiments; and

FIGS. 5a and 5b illustrate an electronic device with different types of packages disposed on a printed circuit board (PCB).

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

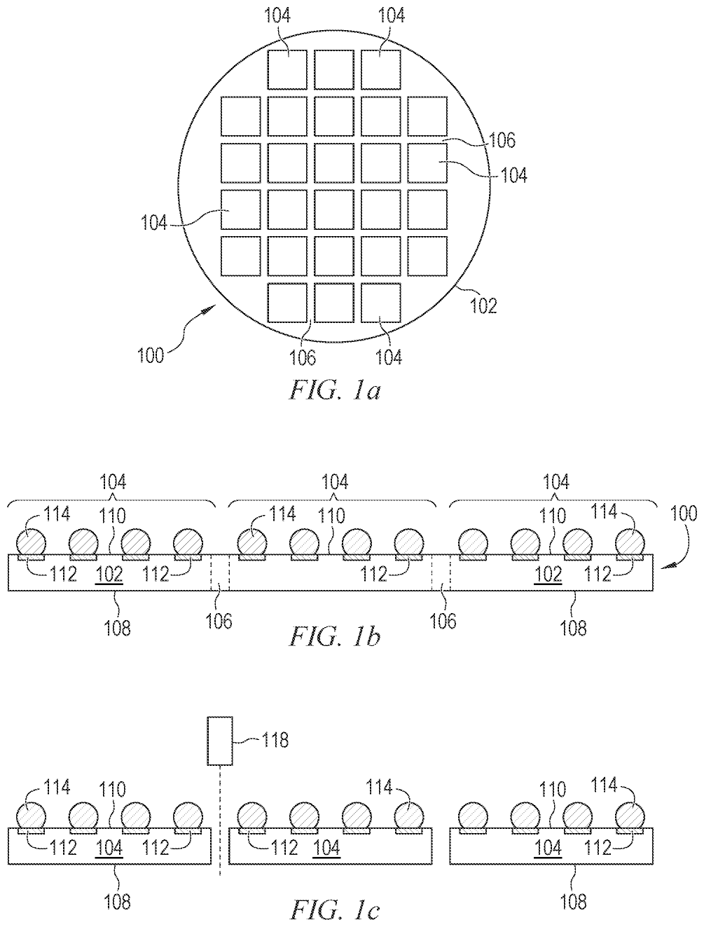

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, or other signal processing circuit. Semiconductor die 104 may also contain integrated passive devices (IPDs), such as inductors, capacitors, and resistors, for RF signal processing.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bumps, micro bumps, or another type of electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

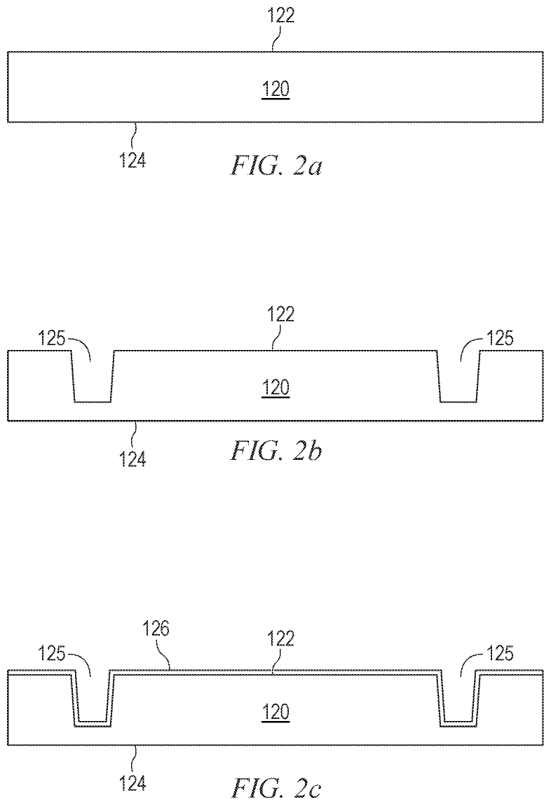

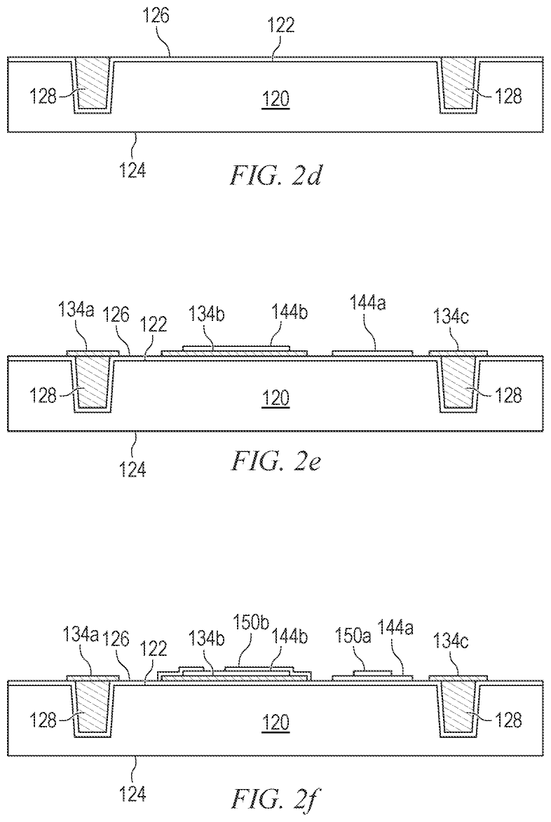

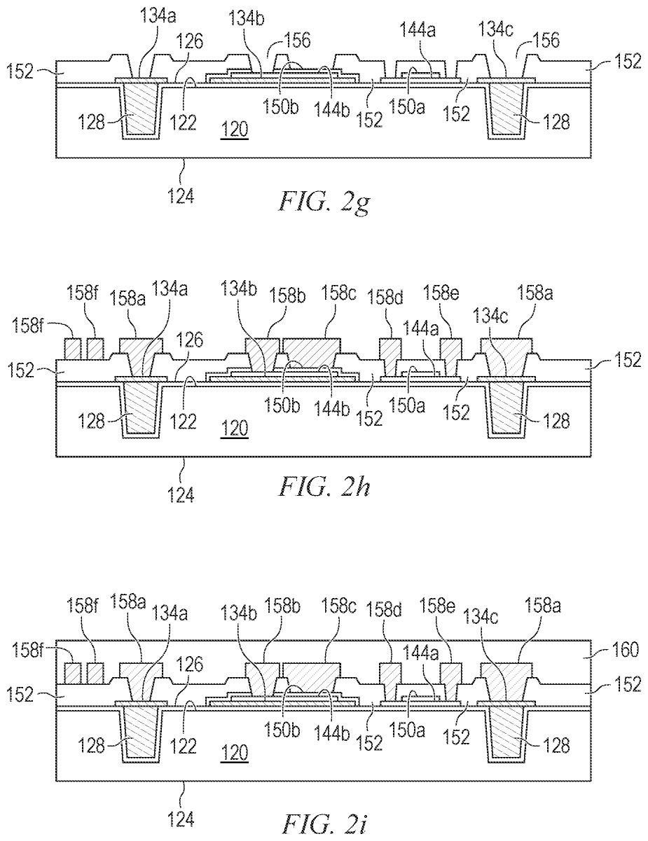

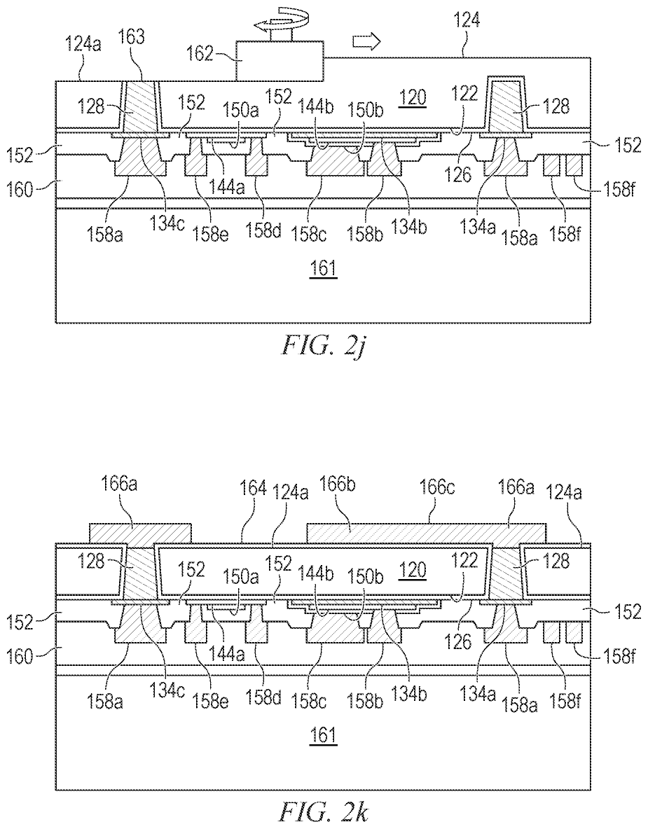

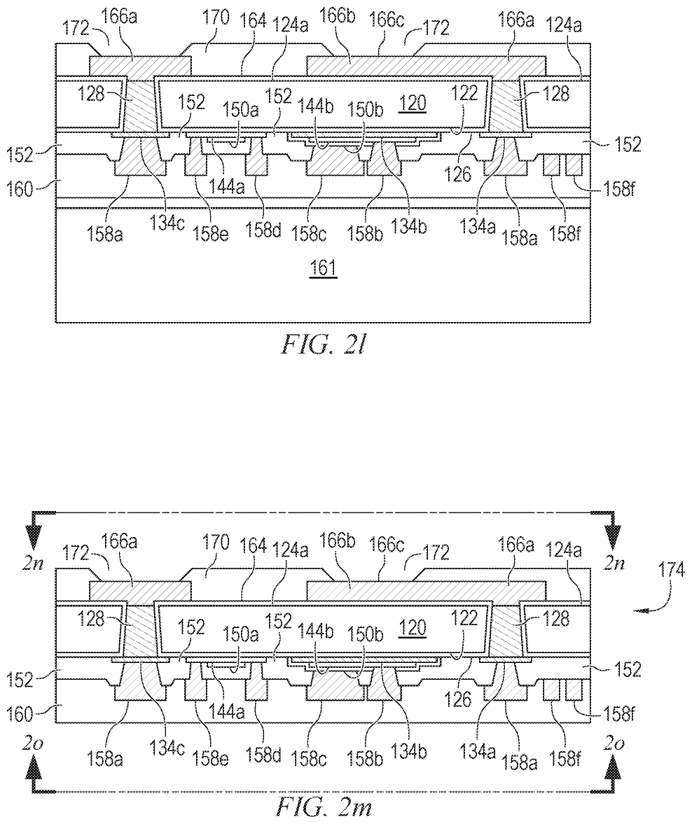

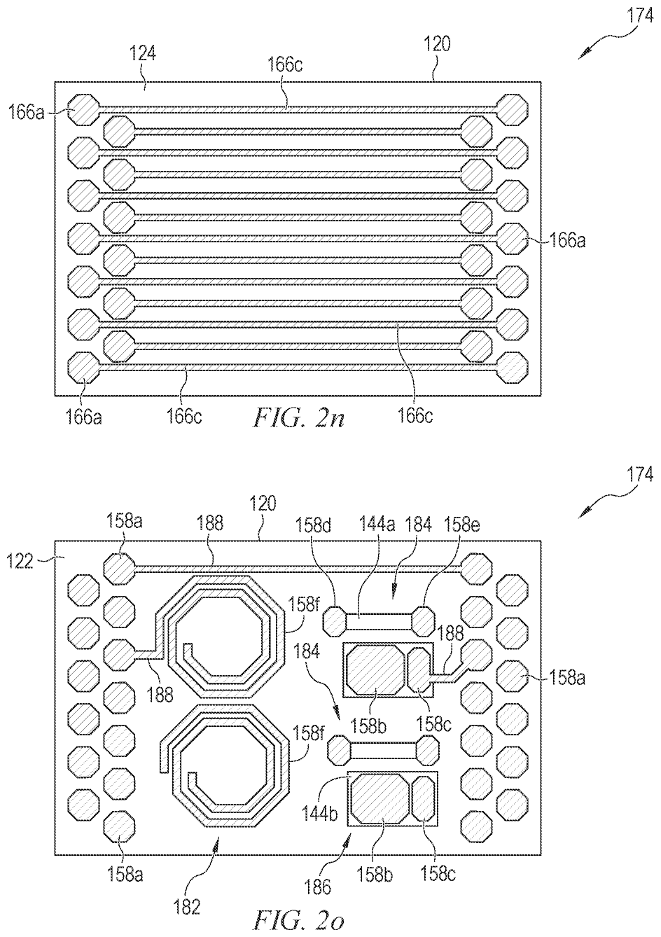

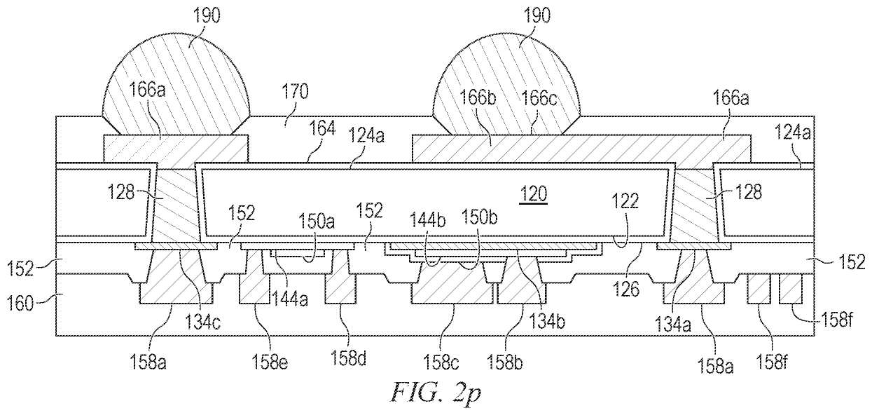

FIGS. 2a-2p illustrate forming IPDs and conductive traces over a substrate to manufacture an interconnect bridge. IPDs are referred to as integrated because passive devices are formed over a substrate using common semiconductor manufacturing steps, allowing the IPDs to easily be integrated onto a semiconductor die with other functionality. A silicon substrate 120 is used in FIG. 2a. Substrate 120 can be the same or similar to wafer 100 in FIG. 1a. In one embodiment, substrate 120 is a high-resistivity silicon (HRS) substrate. Substrate 120 may have active devices formed in the silicon material as with active surface 110 above, or the silicon material can be used only as a substrate for the overlying IPDs. Substrate 120 can also be another semiconductor material, aluminum, steel, copper, another metal, glass, polymer, or formed from any other suitable rigid material for structural support of the IPDs being formed.

Substrate 120 includes two opposing major surfaces 122 and 124. In FIG. 2b, vias 125 are formed into surface 122 and only partially through substrate 120. Vias 125 are formed by chemical etching, deep reactive-ion etching (DRIE), mechanical drilling, or another suitable process. Vias 125 are formed by removing a portion of the material of substrate 120 at locations where vias are desired.

An insulating layer 126 is formed over surface 122 in FIG. 2c. Insulating layer 126 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Openings can be formed through insulating layer 126 to allow electrical connection if active circuit elements were formed in substrate 120. Insulating layer 126 is a conformal coating that has a substantially consistent thickness over the entire surface 122 as well as the surfaces within vias 125.

A conductive material is deposited over surface 122 to form conductive vias or through-silicon vias (TSV) 128 in FIG. 2d. TSV 128 can be one or more layers of Al, Cu, Sn, Ni, Au, Ag, or other suitable electrically conductive material. Conductive layers can be formed using PVD, CVD, electrolytic plating, electroless plating, or other suitable metal deposition process. In some embodiments, conductive material is deposited completely covering surface 122 and filling vias 125, and then backgrinded to remove the conductive material not within vias 125.

A conductive layer 134 is formed over surface 122 and TSV 128 in FIG. 2e. Conductive layer 134 can be formed using any of the materials and processes mentioned above for TSV 128. Conductive layer 134 provides horizontal electrical interconnect across substrate 120. Portions of conductive layer 134 can be electrically common or electrically isolated depending on the design and function of the device being formed. Conductive layer 134 is deposited into openings of insulating layer 126 to physically and electrically connect to circuit elements in substrate 120, if previously formed. Conductive layer 134 is patterned using a photolithographic mask, etching after deposition, or selective plating. Conductive layer 134 has portions 134a and 134c formed directly on TSV 128 to provide an electrical connection to the vias.

In some embodiments, conductive layer 134 is formed in the same manner as a normal metal-1 (M1) layer over a semiconductor die or wafer. Conductive layer 134 is patterned to form integrated passive devices, e.g., shaped in coils to form part of inductors or as a capacitor plate. Portions of conductive layer 134 also form conductive traces across the surface of substrate 120 to act as a redistribution layer (RDL) and contact pads for contact with subsequently formed conductive layers. In particular, portions 134a and 134c are shaped to form a conductive trace with contact pads at its ends and portion 134b is shaped to form a contact pad and a bottom plate of a capacitor connected together. Portions of conductive layer 134 can be shaped as desired to form any suitable circuit elements.

Also, in FIG. 2e, a Tantalum-Silicon (TaSi) layer 144 is formed by depositing the appropriate materials into mask openings over substrate 120. TaSi layer 144 can be deposited using any of the methods discussed above for conductive layer 134. In some embodiments, TaSi layer 144 is formed completely covering a mask layer and then only the portions on the bottom surfaces in openings of the mask layer remain after removal of the mask. In other embodiments, TaSi layer 144 is formed covering substrate 120 completely without a mask and then patterned to the desired formations, or selectively formed in the desired pattern.

TaSi layer 144 is used as a layer with a controllable electrical resistance. In FIG. 2b, portion 144a is formed independently to operate as a resistor. Portion 144b is formed on conductive layer portion 144b to form part of the capacitor structure. TaSi layer 144 can be selectively formed into any desired pattern for forming any desired passive components over substrate 120.

In FIG. 2f, a nitride layer 150 is formed over substrate 120, conductive layer 134, and TaSi layer 144. Nitride layer 150 is selectively formed using a mask or other method as described above for TaSi layer 144. Nitride layer portion 150b is an insulating layer that operates as a dielectric layer over the capacitor plate of conductive layer portion 134b. Nitride layer portion 150a provides a protective layer over the resistor formed by TaSi layer portion 144a. Nitride layer 150 can be formed in any suitable pattern to create the desired electrical components. Other suitable insulating materials are used instead of a nitride in other embodiments.

Insulating layer 152 is formed over substrate 120 in FIG. 2g. Openings 156 are formed through insulating layer 152 to expose underlying elements for electrical interconnect. Insulating layer 152 can be formed as discussed above for insulating layer 126 and patterned using photolithography or another suitable means. Insulating layer 152 is a PI layer in one embodiment.

In FIG. 2h, a conductive layer 158 is formed over insulating layer 152, including extending into openings 156. Conductive layer 158 is formed and patterned as discussed above for conductive layer 134. Portions 158a operate as contact pads for the conductive traces of conductive layer portions 134a and 134c. Portions 158b and 158c operate as contact pads for the underlying capacitor. Portions 158d and 158e operate as contact pads for the underlying resistor. Portions 158f are coiled to form an inductor connected to portion 158a. Inductors can be formed by coiling portions of conductive layer 158, 134, or both together. Conductive layer 158 can be patterned into contact pads, conductive traces, and other structures to implement the desired electrical functionality.

Insulating layer 160 is formed over conductive layer 158 in FIG. 2i. Insulating layer 160 is formed as described above for insulating layer 152. Insulating layer 160 is a PI layer in one embodiment. Openings are optionally formed through insulating layer 160 to expose contact pads of conductive layer 158 where desired for electrical interconnect.

In FIG. 2j, substrate 120 is flipped onto a carrier 161 so that surface 124 is exposed and backgrinded using a mechanical grinder 162. Backgrinding exposes surfaces 163 of TSV 128 that were previously hidden by the silicon material of substrate 120. Backgrinding removes surface 124 of substrate 120 and creates a new surface 124a closer to surface 122, thereby reducing the thickness of substrate 120. In some embodiments, a portion of TSV 128 is removed during backgrinding to ensure that surface 163 is exposed and coplanar to surface 124a.

In FIG. 2k an insulating layer 164 is formed over the coplanar surfaces 124a and 163. Insulating layer 164 is formed using methods and materials as described above for insulating layer 126. Openings are formed through insulating layer 164 to expose TSV 128 for subsequent electrical interconnect using chemical etching, laser etching, mechanical drilling, or another suitable method. In other embodiments, insulating layer 164 is formed using a method that produces the insulating layer over only substrate 120 and not on TSV 128.

A conductive layer 166 is formed over insulating layer 164. Conductive layer 166 is formed using method and materials as described above for conductive layer 158 and other conductive layers. Conductive layer 166 is patterned to include contact pads 166a on TSV 128, other contact pads 166b for external interconnect, and conductive traces 166c to electrically connect the contact pads to each other. In some embodiments, a single contact pad can serve both as a contact point to TSV 128 and also for subsequent electrical interconnect to an external system, in which case no conductive trace 166c is required for that singular contact pad. Some conductive traces may connect between two contact pads 166b when a TSV 128 is not necessary for that particular electrical path, e.g., when the conductive trace is used to interconnect two adjacent semiconductor die and no connection to an IPD on surface 122 is necessary.

An insulating layer 170 is formed over conductive layer 166 in FIG. 2l. Insulating layer 170 is a solder resist or passivation layer in some embodiments. Insulating layer 170 is formed using methods and materials as described above for insulating layer 152 and other insulating layers. Openings 172 are formed over contact pads 166a and 166b wherever the contact pads are used for external interconnect. Carrier 161 is removed in FIG. 2m with an optional thermal, UV, or chemical release to complete an IPD bridge die 174. Substrate 120 is singulated into IPD bridge die 174 in embodiments where the IPD bridge die are formed at a wafer level.

FIG. 2n shows conductive layer 166 formed over surface 124 in one embodiment. Conductive traces 166c each extend from one side of substrate 120 to the opposite side. Contact pads 166a and/or 166b on the two sides are configured to be connected to by two different semiconductor die, one semiconductor die disposed over each opposing side's contact pads. In some embodiments, some contact pads are contact pads 166b without a conductive via extending through substrate 120 and some contact pads 166a do not have conductive traces 166c extending therefrom when the electrical path should only be through IPDs and conductive traces on the opposing surface 124.

FIG. 20 shows a view of substrate 120 from over the surface 122 side in one embodiment. Inductors 182, resistors 184, and capacitors 186 are collectively referred to as IPDs 182-186. Conductive traces 188 connect IPDs 182-186 to each other and to contact pads 158a to implement the desired electrical functionality. While most of the specific electrical connections of IPDs 182-186 are not shown, the IPDs can form any desired passive network, e.g., an RLC matching circuit, RF filter, balun, etc. IPDs 182-186 are formed by conductive layer 134, TaSi layer 144, nitride layer 150, and conductive layer 158.

Resistors 184 are formed by TaSi layer 144a extending between conductive layer portions 158d and 158e. Inductors 182 are formed by conductive layer portions 158f patterned into a coil. Capacitors 186 are formed between conductive layer portions 158b and 158c using TaSi layer 144b and/or nitride layer 150 as the capacitor dielectric. Conductive layer 158 is additionally patterned into conductive traces 188 to electrically couple the IPDs and contact pads 158a to each other. The actual layouts shown in FIG. 2n and 20 are only one example. The actual IPDs and conductive traces formed can be in any suitable combination and pattern to implement any desired electrical functionality.

FIG. 2p illustrates optional solder bumps 190 formed on contact pads 166a and 166b. Solder bumps 190 are formed as described above for bumps 114. IPD interconnect bridge 174 is so named because it is designed to operate as RDL between multiple semiconductor die or other electrical components. IPD bridge 174 has contact pads 166a grouped toward two opposing edges of substrate 120 to connect to two different semiconductor die.

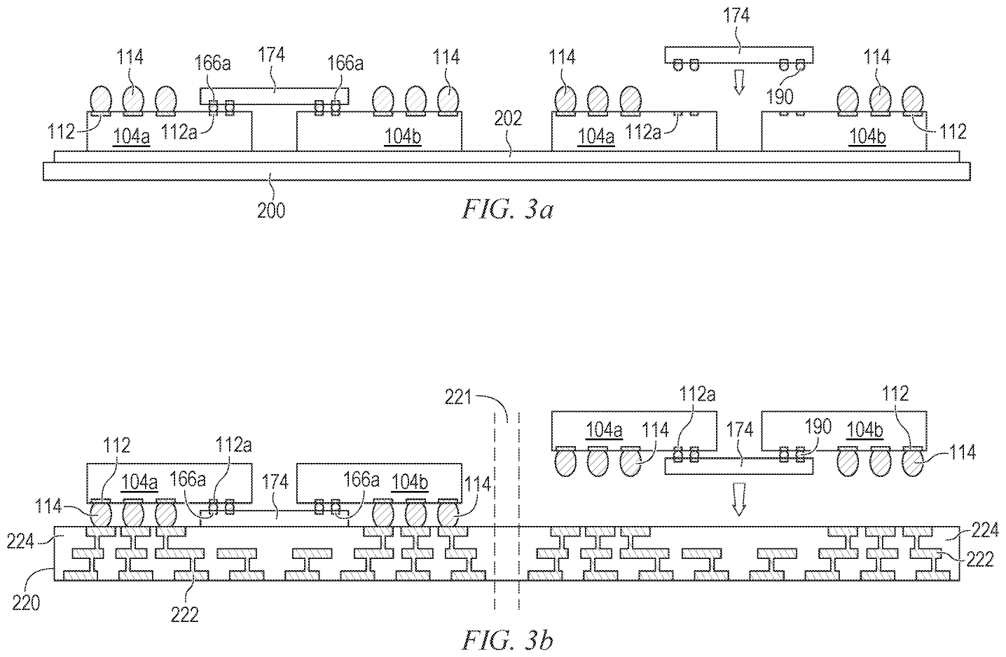

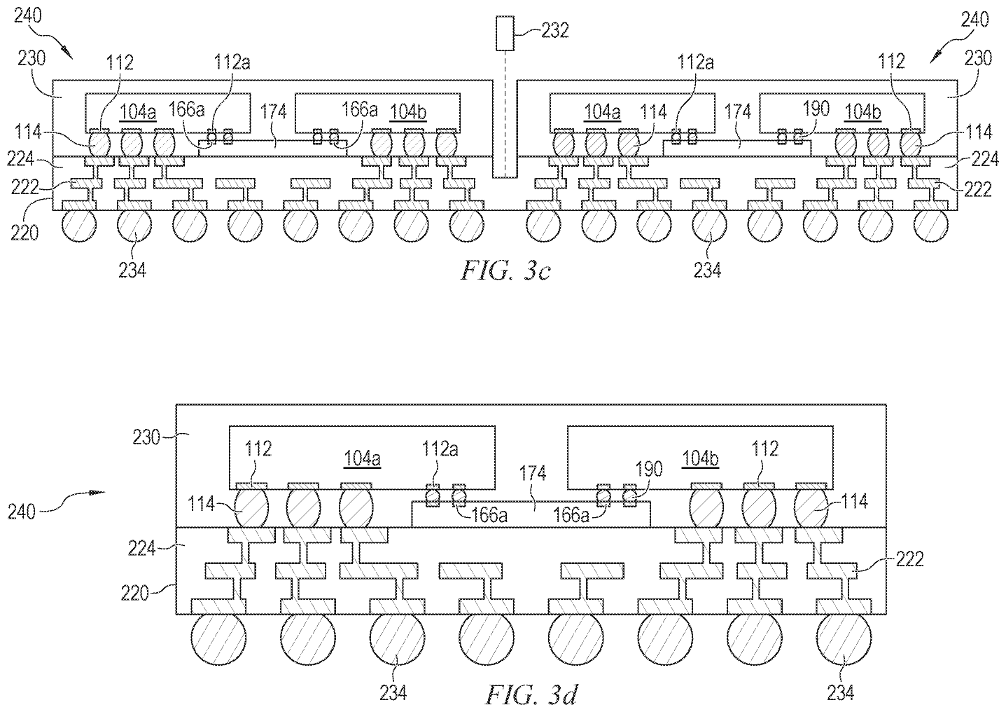

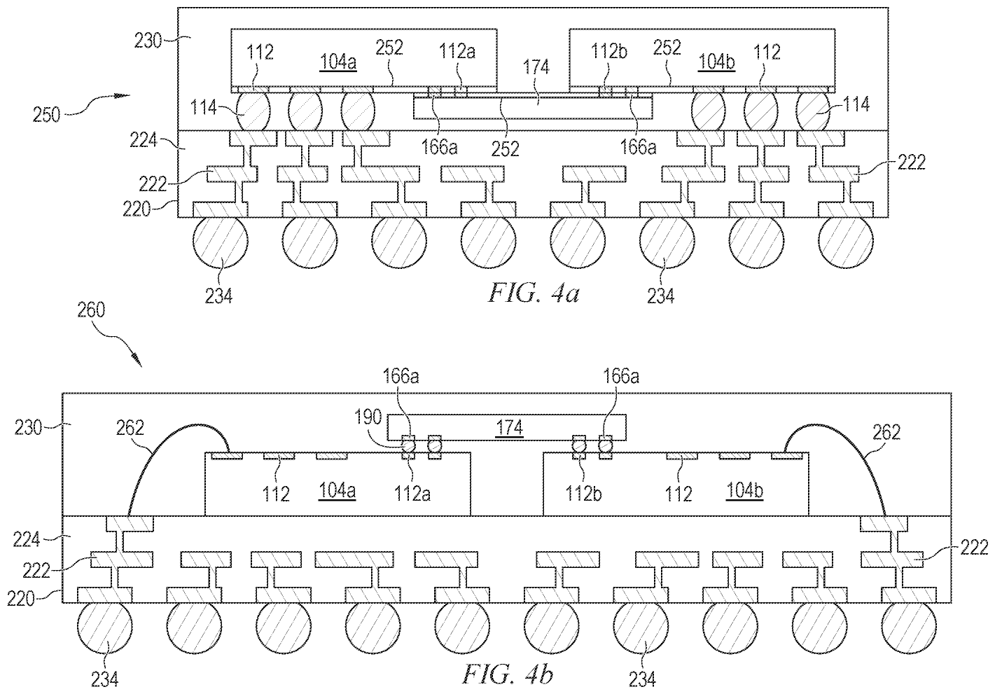

FIGS. 3a-3d illustrate forming semiconductor packages with two semiconductor die 104 connected by IPD bridge 174. In FIG. 3a, semiconductor die 104 are picked and placed onto a carrier or temporary substrate 200 containing sacrificial base material such as silicon, polymer, beryllium oxide, glass, or other suitable low-cost, rigid material for structural support. An interface layer or double-sided tape 202 is formed or disposed over carrier 200 as a temporary adhesive bonding film, thermal release layer, or UV release layer. Carrier 200 can be a round or rectangular panel with capacity for forming multiple packages at once. While only two units are illustrated being formed, hundreds, thousands, or more modules may be formed together on a common carrier 200.

Each package being formed includes two semiconductor die 104a and 104b. Semiconductor die 104a and 104b can be identical to each other and operate in tandem, or be different semiconductor die with cooperative functionality. Some of the contact pads 112, identified with the reference number 112a, remain without bumps 114. Semiconductor die 104a and 104b are placed such that the edges with contact pads 112a are oriented toward each other so that IPD bridge 174 can be picked and placed onto the semiconductor die with bumps 190 aligned to pads 112a of both die. Bumps 190 are reflowed to mechanically and electrically attach IPD bridge 174 to semiconductor die 104a and 104b.

In FIG. 3b, the structure of semiconductor die 104a, semiconductor die 104b, and IPD bridge 174, which was formed in FIG. 3a, is flipped and disposed over a package substrate 220. Substrate 220 is a multi-layered interconnect substrate including conductive layers 222 and insulating layers 224. While only a single substrate 220 suitable to form two semiconductor packages separated by saw street 221 is shown, hundreds or thousands of units are commonly manufactured on, and processed as part of, a single substrate before being singulated from each other, using the same steps described herein performed en masse. A separate substrate 220 could also be used for each package being manufactured, the substrate being singulated before the steps shown in FIGS. 3b-3d and a plurality of individual substrates being placed on a common carrier for processing.

Conductive layers 222 can be one or more layers of Al, Cu, Sn, Ni, Au, Ag, or other suitable electrically conductive material. Conductive layers 222 can be formed using PVD, CVD, electrolytic plating, electroless plating, or other suitable metal deposition process. Conductive layers 222 provide horizontal electrical interconnect across substrate 220 and vertical electrical interconnect between top and bottom surfaces. Portions of conductive layers 222 can be electrically common or electrically isolated depending on the design and function of the package being formed.

Insulating layers 224 contain one or more layers of SiO2, Si3N4, SiON, Ta2O5, Al2O3, solder resist, PI, BCB, PBO, and other material having similar insulating and structural properties. Insulating layers 224 can be formed using PVD, CVD, printing, lamination, spin coating, spray coating, sintering, thermal oxidation, or another suitable process. Insulating layers 224 provide isolation between conductive layers 222. Any number of conductive layers 222 and insulating layers 224 can be interleaved over each other to form substrate 220. Any other suitable type of package substrate or leadframe is used for substrate 220 in other embodiments.

Bumps 114 are reflowed onto contact pads of conductive layer 222 to physically and electrically connect the combination of semiconductor die 104a, semiconductor die 104b, and IPD bridge 174 to substrate 220. A back surface of IPD bridge 174 may rest on the top surface of substrate 220, or a gap may remain. Any additional electrical components can be mounted on the top or bottom surface of substrate 220 as desired to add to the functionality of the package. The additional components can be discrete active or passive devices, additional integrated circuit semiconductor die or packages, antennae, connectors, or any other suitable electrical component.

In FIG. 3c, encapsulant or molding compound 230 is deposited over and around substrate 220, semiconductor die 104a, semiconductor die 104b, and IPD bridge 174 using a paste printing, compressive molding, transfer molding, liquid encapsulant molding, vacuum lamination, spin coating, or another suitable applicator. Encapsulant 230 can be liquid or granular polymer composite material, such as epoxy resin, epoxy acrylate, or polymer, with or without a filler. Encapsulant 230 is non-conductive, provides structural support, and environmentally protects the semiconductor device from external elements and contaminants.

Substrate 220 is flipped, and bumps 234 are mounted onto the bottom surface of the substrate opposite semiconductor die 104. Bumps 234 are formed as described above for bumps 114 of semiconductor die 104. Bumps 234 can be disposed on substrate 220 at any stage of the manufacturing process. FIG. 3c also shows substrate 220 and encapsulant 230 singulated through saw street 221 using saw blade or laser cutting tool 232 into individual semiconductor packages 240. A shielding layer is optionally formed over packages 240 by sputtering.

FIG. 3d shows a completed package 240 with two semiconductor die 104a and 104b connected by IPD bridge 174. IPD bridge 174 includes IPDs usable individually by semiconductor die 104a and semiconductor die 104b, as well as to process signals between the two die. IPD bridge 174 provides significant footprint area for IPDs, which may be limited on the surfaces of semiconductor die 104a and 104b due to signal routing requirements and other logistical issues. IPD bridge 174 includes through-silicon vias to electrically couple IPDs and conductive traces on opposite sides of the IPD bridge to further increase the available footprint area. Both IPD and RDL interconnection are manufactured using a single IPD wafer. Forming RDL on one side of substrate 120 and IPDs on the opposite side of the substrate improves efficiency of footprint usage. In other embodiments, both IPDs and RDL can be formed on both sides of substrate 120.

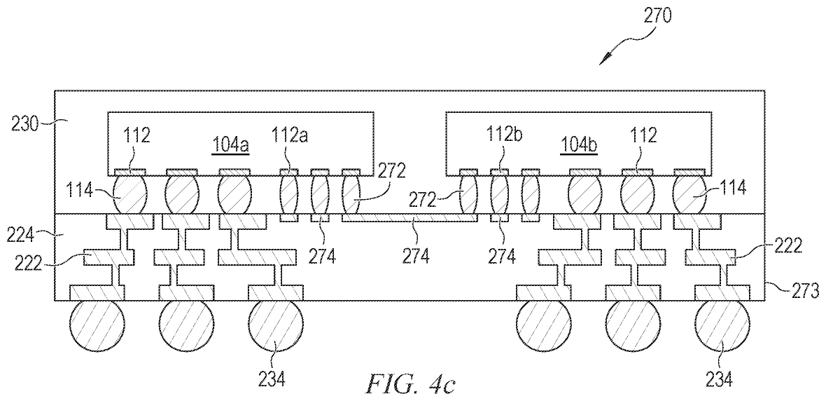

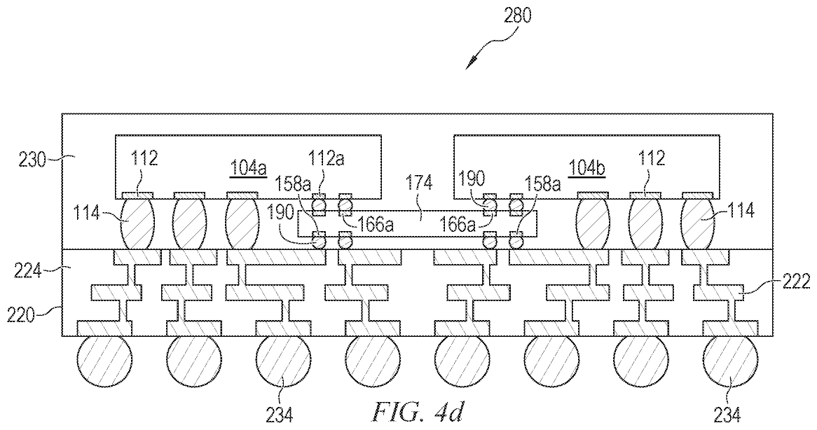

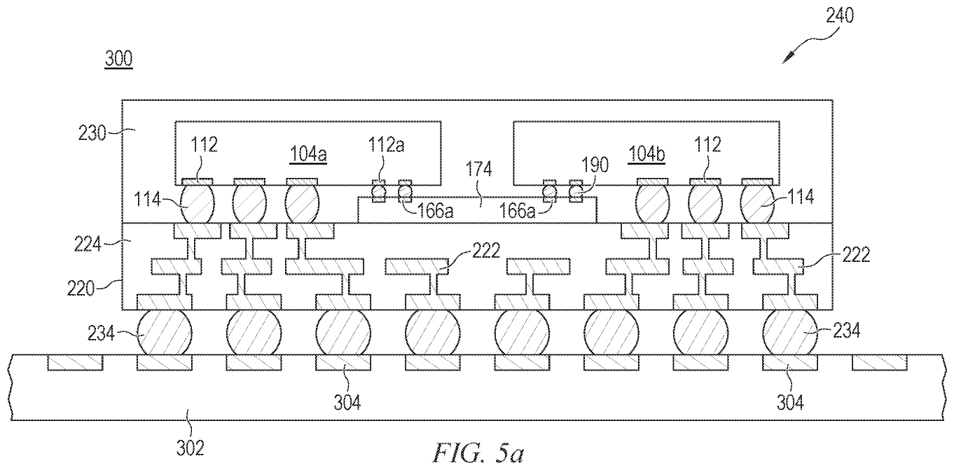

FIGS. 4a-4d illustrate additional embodiments for the interconnections between semiconductor die 104 and IPD bridge 174. In FIG. 4a, package 250 has semiconductor die 104 connected to IPD bridge 174 by hybrid bonding. Hybrid bonding allows direct bonding between contact pads of the devices. IPD bridge 174 is placed on top of two adjacent semiconductor die 104 as shown in FIG. 3a, but without bumps 190 present. The top insulating layer 252 of IPD bridge 174 physically sets directly on the top insulating layers of semiconductor die 104. The opposing insulating layers 252 bond together at room temperature to physically attach IPD bridge 174 to semiconductor die 104a and 104b. Once the insulating layers are bonded together, the combination is heated. Contact pads 112a and 166a expand more than insulating layers 252, thus pressing the contact pads into each other and bonding them together. Other types of thermocompression or hybrid bonding are used in other embodiments. The thermocompression or hybrid bonding is a replacement for solder bumps 190 from FIG. 3d.

FIG. 4b shows an embodiment as semiconductor package 260 with semiconductor die 104 connected to substrate 220 by bond wires 262 instead of bumps 114. Bumps 114 are not formed on semiconductor die 104 as shown in FIG. 1c. Instead, contact pads 112 remain exposed for subsequent bond wire attachment. IPD bridge 174 is mounted to a pair of semiconductor die 104a and 104b as illustrated in FIG. 3a or 4a. The combination of IPD bridge 174 and semiconductor die 104 is then disposed over substrate 220 with back surfaces of the semiconductor die directly on the substrate. Any suitable wire bonding method is used to electrically couple contact pads 112 of semiconductor die 104 to conductive layer 222 of substrate 220. IPD bridge 174 provides electrical connection between semiconductor die 104a and 104b and adds IPD functionality as well.

FIG. 4c illustrates an embodiment where semiconductor package 270 has semiconductor die 104 with bumps 272 connecting contact pads 112a and 112b directly to substrate 273. Conductive layers 274 of substrate 273 provide both interconnect between semiconductor die 104 and also IPDs formed as shown in FIGS. 2e-2i. IPDs can be formed on or in substrate 273 in the same or similar manner as formed on substrate 120 in FIGS. 2a-2p. IPDs can be formed on the opposite surface of substrate 273 while conductive traces are formed on the top surface, similar to IPD bridge 174.

FIG. 4d illustrates an embodiment as semiconductor package 280 with bumps 190 formed on both sides of IPD bridge 174. IPD bridge 174 has openings formed through insulating layer 160 to expose contact pad of conductive layer 158, similar to openings 172 in FIG. 2l. Bumps 190 are formed on the contact pads of conductive layer 158 in addition to being formed on conductive layer 166 as shown in FIG. 2p. During the process step shown in FIG. 3b, bumps 190 are reflowed onto conductive layers 222 along with bumps 114. Having a double-sided IPD bridge 174 increases the options for signal routing and provides direct connection to the IPDs thereon from package substrate 220.

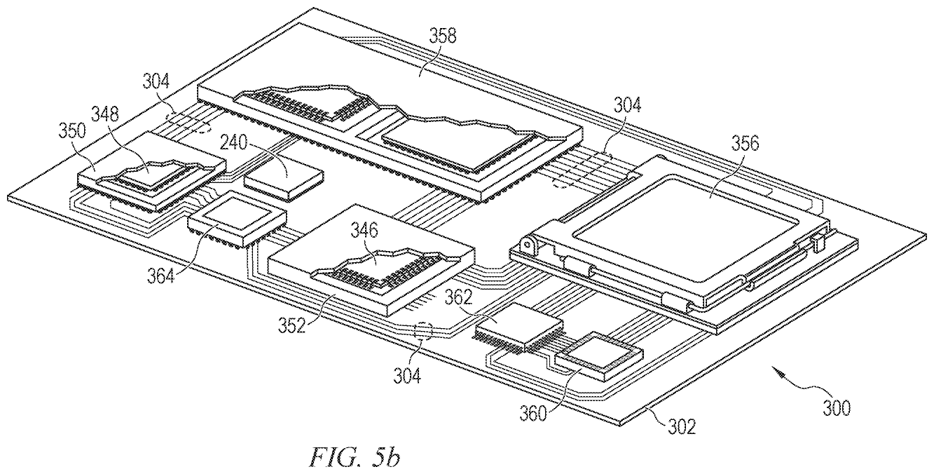

FIGS. 5a and 5b illustrate integrating the above-described semiconductor packages and devices, e.g., semiconductor package 240, into a larger electronic device 300. FIG. 5a illustrates a partial cross-section of semiconductor package 240 mounted onto a printed circuit board (PCB) or other substrate 302 as part of electronic device 300. Bumps 234 are reflowed onto conductive layer 304 of PCB 302 to physically attach and electrically connect semiconductor package 240 to the PCB. In other embodiments, thermocompression or other suitable attachment and connection methods are used. In some embodiments, an adhesive or underfill layer is used between semiconductor package 240 and PCB 302. Semiconductor die 104 are electrically coupled to conductive layer 304 through bumps 234 and substrate 220.

FIG. 5b illustrates electronic device 300 having a chip carrier substrate or PCB 302 with a plurality of semiconductor packages disposed on a surface of PCB 302, including semiconductor package 240. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first substrate;
a first semiconductor die disposed over the first substrate;
a second semiconductor die disposed over the first substrate;
an interconnect bridge disposed over the first semiconductor die and second semiconductor die, wherein the interconnect bridge includes,
a second substrate,
a conductive trace formed over a first surface of the second substrate and electrically coupled from the first semiconductor die to the second semiconductor die,
a conductive via formed through the second substrate, and
an integrated passive device (IPD) formed over a second surface of the second substrate and electrically coupled to the first semiconductor die or second semiconductor die through the conductive via; and
an encapsulant deposited over the first substrate, first semiconductor die, second semiconductor die, and interconnect bridge.

2. The semiconductor device of claim 1, wherein the interconnect bridge is hybrid bonded to the first semiconductor die and second semiconductor die.

3. The semiconductor device of claim 1, further including:
a first solder bump disposed between the first semiconductor die and interconnect bridge; and
a second solder bump disposed between the second semiconductor die and interconnect bridge.

4. The semiconductor device of claim 3, further including a third solder bump disposed between the interconnect bridge and first substrate.

5. The semiconductor device of claim 1, wherein the second substrate comprises a high-resistivity silicon (HRS) substrate.

6. The semiconductor device of claim 1, wherein the integrated passive device includes a resistor, capacitor, or inductor.

7. A semiconductor device, comprising:
a first semiconductor die;
a second semiconductor die; and
an interconnect bridge disposed over the first semiconductor die and second semiconductor die, wherein the interconnect bridge includes,
a substrate,
a conductive trace formed over a first surface of the substrate and electrically coupled from the first semiconductor die to the second semiconductor die, and
an integrated passive device (IPD) formed over a second surface of the substrate.

8. The semiconductor device of claim 7, wherein the interconnect bridge is hybrid bonded to the first semiconductor die and second semiconductor die.

9. The semiconductor device of claim 7, further including:
a first solder bump disposed between the first semiconductor die and interconnect bridge; and
a second solder bump disposed between the second semiconductor die and interconnect bridge.

10. The semiconductor device of claim 7, further including a conductive via formed through the substrate, wherein the IPD is coupled to the conductive trace through the conductive via.

11. The semiconductor device of claim 7, wherein the substrate comprises a silicon substrate.

12. The semiconductor device of claim 7, wherein the integrated passive device includes a resistor, capacitor, or inductor.

13. The semiconductor device of claim 7, further including a bond wire extending from the first semiconductor die.

14. A method of making a semiconductor device, comprising:
providing a first semiconductor die;
disposing a second semiconductor die adjacent to the first semiconductor die;
forming an interconnect bridge by,
providing a substrate,
forming a conductive via through the substrate,
forming an integrated passive device (IPD) over a first surface of the substrate and connected to the conductive via, and
forming a conductive trace over a second surface of the substrate and connected to the conductive via; and
disposing the interconnect bridge over the first semiconductor die and second semiconductor die with the conductive trace electrically coupled between the first semiconductor die and second semiconductor die.

15. The method of claim 14, further including attaching the interconnect bridge to the first semiconductor die and second semiconductor die using hybrid bonding.

16. The method of claim 14, further including forming a second conductive trace over the first surface of the substrate.

17. The method of claim 14, wherein the substrate comprises a silicon substrate.

18. The method of claim 14, wherein the integrated passive device includes a resistor, capacitor, or inductor.

19. The method of claim 14, further including:
disposing the first semiconductor die, second semiconductor die, and interconnect bridge over a second substrate; and
forming a bond wire from the second substrate to the first semiconductor die.

20. A method of making a semiconductor device, comprising:
providing a first electrical component;
disposing a second electrical component adjacent to the first electrical component;
forming an interconnect bridge by,
providing a substrate,
forming a conductive trace over a first surface of the substrate, and
forming an integrated passive device (IPD) over a second surface of the substrate; and
disposing the interconnect bridge over the first electrical component and second electrical component.

21. The method of claim 20, further including attaching the interconnect bridge to the first electrical component and second electrical component using hybrid bonding.

22. The method of claim 20, further including forming a conductive via through the substrate to electrically couple the IPD to the first electrical component.

23. The method of claim 20, wherein the substrate comprises a silicon substrate.

24. The method of claim 20, wherein the integrated passive device includes a resistor, capacitor, or inductor.

25. The method of claim 20, further including:
disposing the first electrical component, second electrical component, and interconnect bridge over a second substrate; and
forming a bond wire from the second substrate to the first electrical component.
